(19) United States
(12) Patent Application Publication
(10) Pub. No.: US 2014/0327155 A1
(43) Pub. Date: Nov. 6, 2014

(54) SEMICONDUCTOR PACKAGE AND METHOD OF MANUFACTURING THE SAME

(71) Applicant: Samsung Electronics Co., Ltd., Suwon-si (KR)

(72) Inventors: Taegyu Kang, Chungcheongnam-do (KR); Minchul Kim, Chuncheongnam-do (KR); Sung-Jin Kim, Chuncheongnam-do (KR); Kyeongjun Song, Chuncheongnam-do (KR)

(73) Assignee: Samsung Electronics Co., Ltd., Suwon-si (KR)

(21) Appl. No.: 14/134,589

(22) Filed: Dec. 19, 2013

(30) Foreign Application Priority Data
May 2, 2013 (KR) 10-2013-0049508

(51) Int. Cl. H01L 23/28; H01L 23/00; H01L 25/065

(52) U.S. Cl. CPC H01L 23/28; H01L 25/0657; H01L 23/562
USPC 257/777

(57) ABSTRACT

A semiconductor package comprises a lower package comprising a lower substrate, a lower semiconductor chip mounted on a surface of the lower substrate, connection terminals between the lower substrate and the lower semiconductor chip, and a protection film covering the lower semiconductor chip. An upper package is spaced apart from the lower package on an upper surface of the lower substrate, the upper package comprising an upper substrate and an upper semiconductor chip. Connections are present between the lower substrate and the upper substrate to horizontally surround the lower semiconductor chip. A molding film is on the upper surface of the lower substrate to fill spaces between the connection terminals and the connections. An uppermost surface of the protection film is positioned at substantially a same vertical level as an uppermost surface of the molding film and is spaced apart from the upper package.

### CROSS-REFERENCE TO RELATED APPLICATIONS

This U.S. non-provisional patent application claims priority under 35 U.S.C. §119 to Korean Patent Application No. 10-2013-0049508, filed on May 2, 2013, the entire content of which is hereby incorporated by reference.

### BACKGROUND

The present disclosure herein relates to a semiconductor, and more particularly, to a semiconductor package and a method of manufacturing the same.

The electronics industry continues to endeavor to provide lightweight, miniaturized, high-response-rate, and high performance electronic products at an efficient cost. In line with such electronic industry trends, semiconductor device technology in which a plurality of semiconductor chips or semiconductor packages are realized in the same, single package is being emphasized. Various studies are being conducted to improve the reliability of such semiconductor devices.

### SUMMARY

In an aspect, a semiconductor package comprises: a lower package comprising a lower substrate, a lower semiconductor chip mounted on a surface of the lower substrate, connection terminals between the lower substrate and the lower semiconductor chip, and a protection film covering the lower semiconductor chip; an upper package spaced apart from the lower package on an upper surface of the lower substrate, the upper package comprising an upper substrate and an upper semiconductor chip; connections between the lower substrate and the upper substrate to horizontally surround the lower semiconductor chip; and a molding film on the upper surface of the lower substrate to fill spaces between the connection terminals and the connections; wherein an uppermost surface of the protection film is positioned at substantially a same level as an uppermost surface of the molding film and is spaced apart from the upper package.

In some embodiments, a gap is provided between the lower package and the upper package, and the protection film is exposed to the gap.

In some embodiments, the upper substrate is disposed on the connections, and wherein the upper semiconductor chip is disposed on the upper substrate.

In some embodiments, an uppermost surface of the connections is positioned at a level higher than the uppermost surface of the protection film.

In some embodiments, the lower semiconductor chip comprises: a bottom surface facing the substrate, a top surface opposite the bottom surface, and a side surface between the bottom surface and the top surface, wherein the top surface is covered by the protection film, and the side surface is covered by the molding film.

In an aspect, a method of manufacturing a semiconductor package comprises: providing a lower semiconductor chip having top and bottom surfaces opposite each other; forming a protection film on the top surface of the lower semiconductor chip; mounting the lower semiconductor chip on a lower substrate such that the bottom surface of the semiconductor chip faces the lower substrate; forming a molding film on the lower substrate to seal the lower semiconductor chip; and mounting an upper package on the lower substrate to electrically connect the upper package to the lower substrate, wherein a lower surface of the upper package is mounted spaced apart from the protection film.

In some embodiments, forming the molding film comprises filling an epoxy molding compound on the lower substrate so that an uppermost surface of the molding film is substantially coplanar with an uppermost surface of the protection film.

In some embodiments, the upper package comprises: an upper substrate facing the lower package; and an upper semiconductor chip disposed on the upper substrate.

In some embodiments, the mounting of the upper package further comprises forming connections between the lower substrate and the upper substrate to horizontally surround the lower semiconductor chip, wherein the connections electrically connect the upper substrate to the lower substrate.

In some embodiments, the mounting of the lower semiconductor chip on the lower substrate comprises forming connection terminals between the lower substrate and the lower semiconductor chip to electrically connect the lower semiconductor chip to the lower substrate.

In an aspect, a semiconductor package comprises: a lower package having terminals; an upper package on the lower package, the upper package having terminals; conductive package connections electrically connecting the terminals of the lower package and the upper package; the lower package comprising: a lower semiconductor chip mounted to and electrically interfacing with a lower substrate, the conductive package connections horizontally surrounding the lower semiconductor chip; a protection layer on a top surface of the lower semiconductor chip, the protection layer having an upper surface; and a mold layer on the lower substrate and between the conductive package connections and sidewalls of the lower semiconductor chip; wherein the conductive package connections are of a height that is greater than a combined height of the lower semiconductor chip and the protection layer such that a gap is present between the lower package and upper package.

In some embodiments, the gap comprises an air gap.

In some embodiments, the upper surface of the protection layer interfaces with the air gap.

In some embodiments, the protection layer at least partially covers a top surface of the lower semiconductor chip.

In some embodiments, the protection layer completely covers the top surface of the lower semiconductor chip.

In some embodiments, the mold layer covers entire sidewalls of the lower semiconductor chip.

In some embodiments, the mold layer covers entire sidewalls of the protection layer.

In some embodiments, the semiconductor package further comprises lower electrical connectors connecting terminals at an underside of lower semiconductor chip with terminals of an upper surface of the lower substrate, and wherein the mold layer is further present between the lower electrical connectors.

In some embodiments, the upper package comprises an upper substrate and an upper semiconductor chip on the upper substrate.

In some embodiments, the upper surface of the protection layer is at substantially a same vertical position as an upper surface of the mold layer.

### BRIEF DESCRIPTION OF THE DRAWINGS

The accompanying drawings are included to provide a further understanding of the inventive concepts, and are incorporated in, and constitute a part of, this specification. The drawings illustrate exemplary embodiments of the inventive concepts and, together with the description, serve to explain principles of the inventive concepts. In the drawings:

FIG. 1 is a cross-sectional view illustrating a semiconductor package according to an embodiment of the inventive concepts;

FIGS. 2 to 4 are cross-sectional views illustrating a method of manufacturing a semiconductor package according to an embodiment of the inventive concepts;

FIG. 5 is a cross-sectional view illustrating a manufacturing process of a molding film according to an embodiment of the inventive concepts;

FIG. 6 is a cross-sectional view illustrating a manufacturing process of a semiconductor package according to an embodiment of the inventive concepts;

FIG. 7 is a block diagram illustrating an example of an electronic device including a semiconductor package to which a feature of the inventive concepts is applied; and

FIG. 8 is a block diagram illustrating an example of a memory system including a semiconductor package to which a feature of the inventive concepts is applied.

### DETAILED DESCRIPTION OF EMBODIMENTS

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, a semiconductor package will be described according to the inventive concepts.

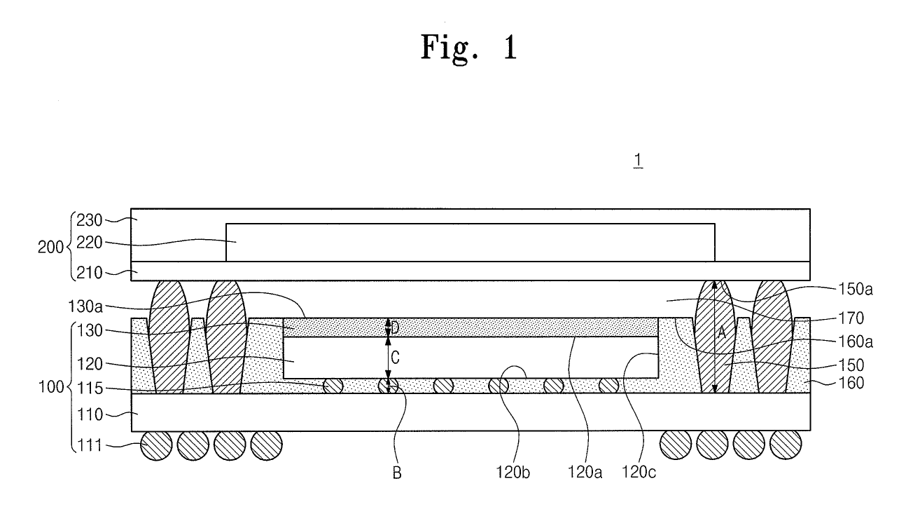

FIG. 1 illustrates a cross-sectional view of a semiconductor device according to an embodiment of the inventive concepts.

Referring to FIG. 1, the semiconductor package 1 may include a lower package 100, connections 150, a molding film 160, and an upper package 200. A gap 170 may be present between the lower package 100 and the upper package 200.

In some embodiments, the lower package 100 may include a lower substrate 110, an external terminal 111, connection terminals 115, a lower semiconductor chip 120, and a protection film 130. In some embodiments, the lower package 100 may be a flip chip device in which the lower semiconductor chip 120 is mounted in a face-down orientation on the lower substrate 110. In some embodiments, the lower substrate 110 may comprise a printed circuit board (PCB) having circuit patterns. The connection terminals 115 may be disposed between the lower substrate 110 and the lower semiconductor chip 120 to electrically connect terminals of the lower semiconductor chip 120 with terminals the lower substrate 110. In some embodiments, the connection terminals 115 may comprise a conductive material and may have a solder or a bump shape. In some embodiments, the external terminal 111 may be disposed on a bottom surface of the lower substrate 110. In some embodiments, the external terminals 111 may include a conductive material and may take the shape of a solder ball. The external terminals 111 may electrically connect terminals of the upper semiconductor chip 220 and the lower semiconductor chip 120 to an external electronic device.

In some embodiments, the lower semiconductor chip 120 may be mounted on the lower substrate 110. The lower semiconductor chip 120 may have a top surface 120a, a bottom surface 120b facing the top surface 120a, and a side surface 120c connecting the top surface 120a and the bottom surface 120b. In some embodiments, the top surface 120a may be an active surface, and the bottom surface 120b may be a non-active surface. In other embodiments, the bottom surface 120b may also be an active surface. The top surface 120a of the lower semiconductor chip 120 may be sealed by or covered by, and in contact with, the protection film 130. The side surface 120a of the lower semiconductor chip may be sealed by or covered by, and in contact with, the molding film 160. In some embodiments, the lower semiconductor chip 120 may include an integrated circuit, for example, a memory circuit, a logic circuit, or a combination thereof.

In some embodiments, the protection film 130 may cover the top surface 120a of the lower semiconductor chip 120. In some embodiments, an upper portion of the protection film 130 may be exposed to the gap 170 by the molding film 160. The protection film 130 may have an uppermost surface 130a which is positioned at the same level as an uppermost surface 160a of the molding film 160, so as to be substantially co-planar. The uppermost surface 130a of the protection film 130 may be positioned at a lower level than an uppermost surface 150a of the connections 150, and thus is spaced apart from the upper package 200. In some embodiments, the protection film 130 may have the same horizontal planar area as that of the lower semiconductor chip 120. The protection film 130 may prevent the top surface 120a of the lower semiconductor chip 120 from being exposed to the gap 170. As a result, the lower semiconductor chip 120 has reduced exposure to external stress. As the lower semiconductor chip 120 is operated, heat may be generated by the active regions of the chip 120 and discharged to external regions through the protection film 130 and the gap 170. Thus, the lower semiconductor chip 120 may realize higher operation reliability than a case in which the gap 170 is omitted.

In some embodiments, the connections 150 may be disposed on the lower substrate 110 to horizontally surround the lower semiconductor chip 120. In some embodiments, the connections 150 may be disposed between the lower substrate 110 and the upper substrate 210 to electrically connect terminals of the upper package 200 to terminals of the lower substrate 110. In some embodiments, the connections 150 may have a bump or a solder ball shape. The connections 150 may comprise a conductive material. In some embodiments, the connections 150 may have a height A which is greater than the sum of a height B of the connection terminals 115, a height C of the lower semiconductor chip 120, and a height D of the protection film 130. Thus, the protection film 130 may be spaced apart from the lower package 200, for example, by a gap 170. In some embodiments, the gap 170 comprises an air gap.

The molding film 160 may be disposed on the lower substrate 110 to fill spaces between the connections 150 and between the connection terminals 115. In some embodiments, the molding film 160 may extend along the side surface 120c of the lower semiconductor chip 120. In some embodiments, the molding film 160 may comprise an insulating polymer material, such as an epoxy molding compound. In some embodiments, the uppermost surface 160a of the molding film 160 may be positioned at a higher level than the top surface 120a of the lower semiconductor chip 120. In some embodiments, the uppermost surface 160a of the molding film 160 may be positioned at the same level as, or substantially coplanar with, the uppermost surface 130a of the protection film 130. The uppermost surface 160a of the molding film 160 may be spaced apart from the upper package 200 and may be exposed to the gap 170.

The upper package 200 may comprise an upper substrate 210, an upper semiconductor chip 220 mounted on the upper substrate 210, and an upper molding film 230. In some embodiments, the upper substrate 210 may comprise a printed circuit board (PCB) having circuit patterns. In some embodiments, the upper package 200 may be electrically connected to the lower package 100 by the connections 150. In some embodiments, the upper package 200 may be molded by the upper molding film 230. The upper molding film 230 may be disposed on the upper substrate 210 to cover the upper semiconductor chip 220. In various embodiments, the upper semiconductor chip 220 may be mounted on the upper substrate 210 by a die bonding, a wire bonding, or a flip chip bonding. The upper semiconductor chip 220 may be disposed in a position that is at least partially vertically above the lower semiconductor chip 120.

Hereinafter, a method of manufacturing the semiconductor package according to the inventive concepts will be described.

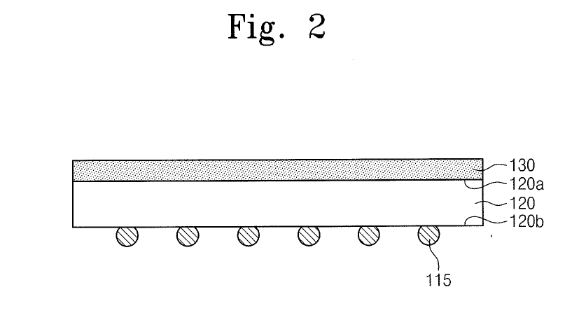

FIGS. 2 to 5 are cross-sectional views illustrating a method of manufacturing a semiconductor package according to an embodiment of the inventive concepts.

Referring to FIG. 2, a lower semiconductor chip 120 may be provided. A protection film 130 may be formed on a top surface 120a of the lower semiconductor chip 120. In an example, the protection film 130 may be provided by attaching a protection tape on the top surface 120a of the lower semiconductor chip 120. In another example, the forming of the protection film 130 may include coating a liquid adhesive material on the top surface 120a of the lower semiconductor chip 120 and curing the coated adhesive material. In some embodiments, the protection film 130 is positioned to cover the top surface 120a of the lower semiconductor chip 120. Thus, due to the presence of the protection film 130, the lower semiconductor chip 120 is prevented from becoming damaged by external stress during the process of forming the semiconductor package. Connection terminals 115 having a solder ball shape may be provided on a bottom surface 120b of the lower semiconductor chip 120. In some embodiments, the connection terminals 115 may include a conductive material.

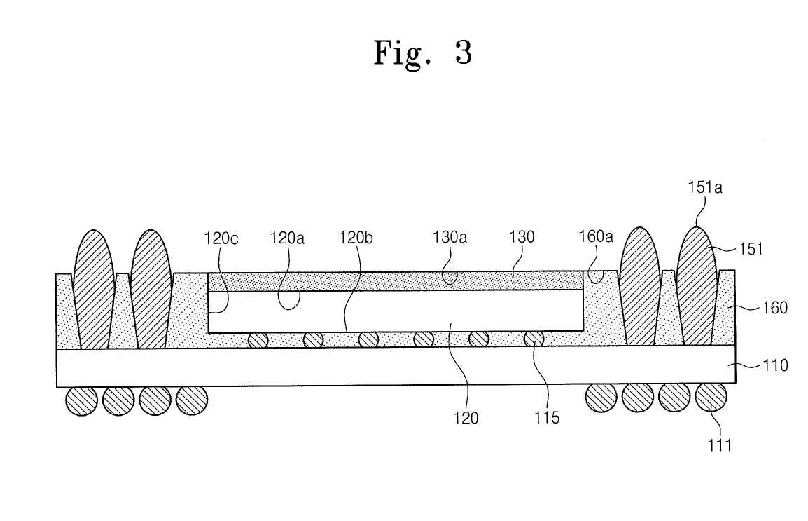

Referring to FIG. 3, the lower semiconductor chip 120 may be mounted on a lower substrate 110 such that a bottom surface 120 of the lower semiconductor chip 120 is oriented to face the lower substrate 110. Connection terminals 115 may be disposed between the lower substrate 110 and the lower semiconductor chip 120 to electrically connect terminals of the lower semiconductor chip 120 and the lower substrate 110. The lower substrate 110 may be a substrate on which solder balls 151 are formed. In some embodiments, the solder balls 151 may comprise a conductive material. The solder balls 151 may be disposed on the lower substrate 110 and positioned to horizontally surround the lower semiconductor chip 120. In some embodiments, a molding film 160 may fill a space between the connections 150 and a space between the connection terminals 115. In some embodiments, the molding film 160 may be disposed on the lower substrate 110 to surround and seal a side surface 120c of the lower semiconductor chip 120. In some embodiments, the uppermost surface 160a of the molding film 160 may be positioned at the same level as an uppermost surface 130a of the protection film 130 to be substantially coplanar with the uppermost surface 130a of the protection film 130. In some embodiments, the thickness of the molding film 160 may selected so as to expose the solder balls 151. In some embodiments, external terminals 111 may be formed on a bottom surface of the lower substrate 110. In some embodiments, the external terminals 111 may comprise a conductive material and have a solder ball shape.

The above-described formation of solder balls 151 and attachment of the external terminal 111 are not limited to the above-presented sequence. In an example, the forming of the solder balls 151, the mounting of the lower semiconductor chip 120, the forming of the molding film 160, and the attaching of the external terminal 111 may be sequentially performed. In another example, the mounting of the lower semiconductor chip 120, the forming of the molding film 160, and the forming of the solder balls 151 may be sequentially performed. In this case, the molding film 160 may be patterned to expose the lower substrate 110 and then the solder balls 151 may be disposed on the exposed lower substrate 110. Other formation sequences are also possible and applicable to the inventive concepts.

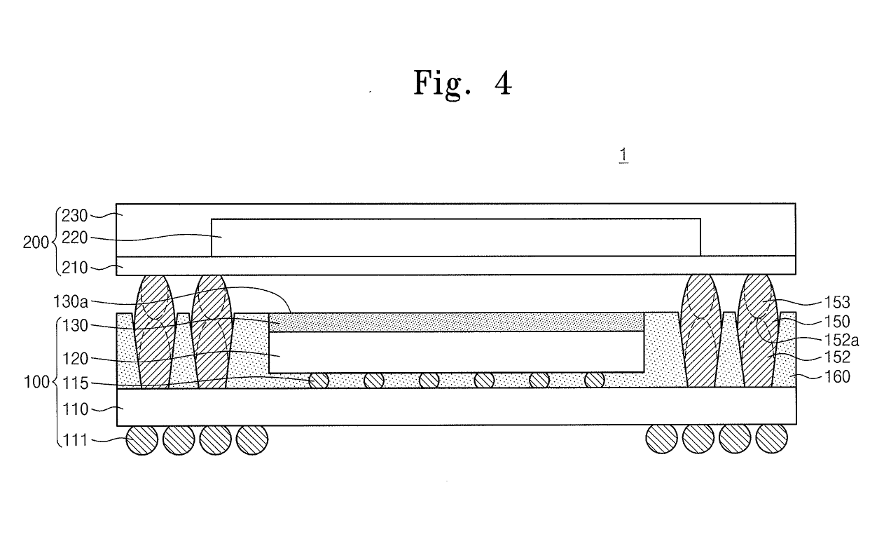

Referring to FIG. 4 together with FIG. 3, an upper package 200 including an upper substrate 210, an upper semiconductor chip 220, and an upper molding film 230 may be mounted on the lower substrate 110. In some embodiments, the upper substrate 210, the upper semiconductor chip 220, and the upper molding film 230 may be the same as or similar to those exemplified in FIG. 1. Terminals of the upper package 200 may be electrically connected to terminals of the lower substrate 110 and the lower semiconductor chip 120 by the connections 150. An uppermost surface 150a (see FIG. 1) of the connections 150 may be positioned at a higher level than the uppermost surface 130a of the protection film 130, so that accordingly the upper package 200 may be spaced apart from the protection film 130 and the molding film 160. As a result, a gap 170 may be present between the protection 130 and the upper package 200. In an example, the connections 150 may be manufactured from the solder balls 151 positioned at a higher level than the uppermost surface 130a of the protection film 130 as illustrated in FIG. 3. The upper substrate 210 may be oriented or positioned to face the lower package 100 and attached to the connections 151. In another example, as illustrated by dotted lines in FIG. 4, solder balls 152 having an uppermost surface 152a which is positioned at a lower level than the uppermost surface 130a of the protection film 130 may be provided. In this case, upper solder balls 153 may be formed on the bottom surface of the upper substrate 210. The upper solder balls 153 may be disposed to correspond to the solder balls 152 formed on the lower substrate 110, respectively. The lower solder balls 152 may be connected to the upper solder balls 153 by soldering to provide the resulting connections 150.

Hereinafter, a function of the protection film according to the inventive concepts will be described.

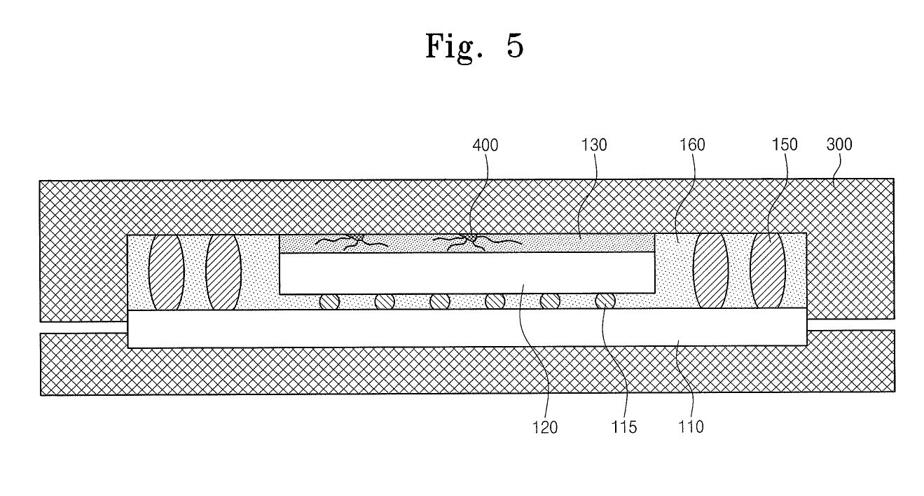

FIG. 5 is a cross-sectional view illustrating a process of manufacturing a molding film according to an embodiment of the inventive concepts.

Referring to FIG. 5, during manufacturing of the molding film, a foreign substance 400 may be placed in contact with the protection film 130. A lower substrate on which a lower semiconductor chip 120, a protection film 130, and solder balls 150 are formed may be positioned in a mold apparatus 300. The forming of the lower semiconductor chip 120, the protection film 130, and the solder balls 150 may be the same as or similar to the process described in connection with the example embodiments of FIGS. 2 and 3. The mold 300 may move to contact the lower substrate 110 and the protection film 130. An epoxy molding compound may be supplied on the lower substrate 110 to form a molding film 160 having an uppermost surface which is positioned at substantially the same level as the protection film 130. In this process, the mold 300 may physically press the protection film 130. The foreign substance 400 may act as a physical stress such as a crack seed with respect to the protection film 130. Properties of the protection film 130 allow it to absorb the physical stress applied by the foreign substance 400 and/or the mold 300 to thereby protect the lower semiconductor chip 120. In another example, the protection film 300 may become damaged instead of the lower semiconductor chip 120. Accordingly, damage such as a crack can be prevented from being generated in the lower semiconductor chip 120.

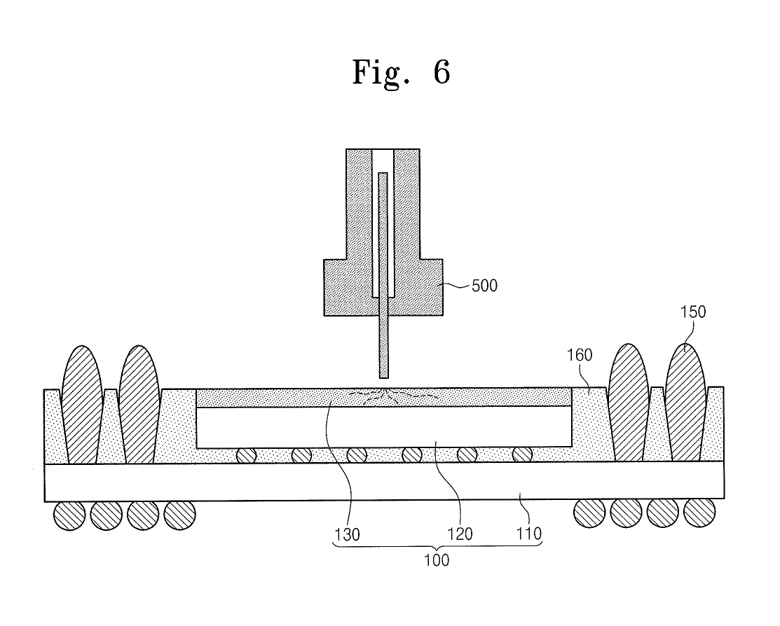

FIG. 6 is a cross-sectional view illustrating a process of manufacturing of a semiconductor package according to the inventive concepts.

Referring to FIG. 6, after the molding film 160 is applied to the lower package 100, the resulting structure can be moved to a tray. In some embodiments, the moving of the lower package 100 may be performed by using a transfer device 500 such as a picker. Absent the protection film 130, the transfer device 500 may come in direct contact with the lower semiconductor chip 120. As a result, the lower semiconductor chip 120 can become physically damaged. According to embodiments of the inventive concepts, the transfer device instead interfaces with the protection film 130. As a result, the lower semiconductor chip 120 is prevented from becoming damaged by the transfer device 500 during transport of the lower semiconductor chip 120 during manufacture.

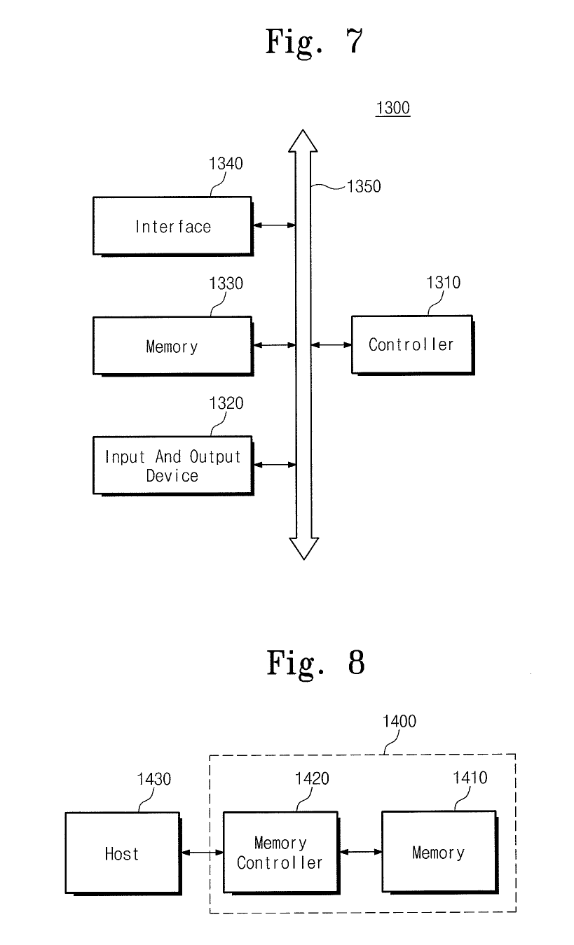

FIG. 7 is a block diagram illustrating an example of an electronic device including a semiconductor package according to an embodiment of the inventive concepts. FIG. 8 is a block diagram illustrating an example of a memory system including a semiconductor package according to an embodiment of the inventive concepts.

Referring to FIG. 7, an electronic system 1300 may include a controller 1310, an input/output device 1320 and a memory 1330. The controller 1310, the input/output device 1320, and the memory 1330 may be coupled to each other through a bus 1350. The bus 1350 is a path through which data is transmitted. For example, the controller 1310 may include at least one of at least one microprocessor, a digital signal processor, a microcontroller, and logic devices that are capable of performing the same function that of the microprocessor, the digital signal processor, or the microcontroller. The controller 1310 and the memory 1330 may include a semiconductor package 1 according to embodiments of the inventive concepts. The input/output device 1320 may include at least one selected from a keypad, a keyboard, and a display device. The memory 1330 is a device for storing data. The memory 1330 may store data and/or commands executed by the controller 1310. The memory 1330 may include a volatile memory and/or a nonvolatile memory. Alternately, the memory 1330 may comprise a flash memory. For example, a flash memory in which a feature of the inventive concepts is applied may be mounted to an information processing system such as a mobile device, or a desktop computer. This flash memory may constitute a solid state drive. In this case, the electronic system 1300 may stably store massive data in the flash memory system. The electronic system 1300 may further include an interface 1340 for transmitting data through a communication network, or for receiving data from the communication network. The interface 1340 may be a wire-wireless type interface. For example, the interface 1340 may include an antenna, or a wire-wireless transceiver. Although not shown, it is obvious to those skilled in the art that an application chipset, a camera image processor (CIS), an input/output device, or the like may be further applied to the electronic system 1300.

The electronic system 1300 may be realized as a mobile system, a personal computer, an industrial computer, or a logic system performing various functions. For example, the mobile system may be at least one of a personal digital assistant (PDA), a portable computer, a web tablet, a mobile phone, a wireless phone, a laptop computer, a memory card, a digital music system, and an information transmission/reception system. If the electronic system 1300 is a device that is capable of performing a wireless communication, the electronic system 1300 may be used in a communication interface protocol such as the third generation communication system, for example, code division multiple access (CDMA), global standard for mobile communication (GSM), north American digital cellular (NADC), extended time division multiple access (E-TDMA), wideband code division multiple access (WCDAM) and CDMA 2000.

Referring to FIG. 8, a memory card 1400 may include a nonvolatile memory 1410 and a memory controller 1420. The nonvolatile memory 1410 and the memory controller 1420 may store data or read the stored data. The nonvolatile memory 1410 may include a semiconductor package 1 according to embodiments of the inventive concepts. The memory controller 1420 may read stored data in response to read/write request of a host or may control the flash memory 1410 to store data.

The semiconductor package according to the inventive concepts may include the protection film on the lower semiconductor chip to thereby prevent the lower semiconductor chip from becoming damaged as a result of the presence of foreign substances or external stress that can be present or applied during device manufacture. Therefore, the semiconductor package may be improved in reliability.

The subject matter disclosed herein is to be considered illustrative and not restrictive, and the appended claims are intended to cover all such modifications, enhancements, and other embodiments, which fall within the true spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

1. A semiconductor package comprising:
a lower package comprising a lower substrate, a lower semiconductor chip mounted on an upper surface of the lower substrate, connection terminals between the lower substrate and the lower semiconductor chip, and a protection film covering the lower semiconductor chip;
an upper package spaced apart from the lower package on the upper surface of the lower substrate, the upper package comprising an upper substrate and an upper semiconductor chip;
connections between the lower substrate and the upper substrate to horizontally surround the lower semiconductor chip; and
a molding film on the upper surface of the lower substrate to fill spaces between the connection terminals and the connections;
wherein an uppermost surface of the protection film is positioned at substantially a same level as an uppermost surface of the molding film and is spaced apart from the upper package.

2. The semiconductor package of claim 1, wherein a gap is provided between the lower package and the upper package, and the protection film is exposed to the gap.

3. The semiconductor package of claim 1, wherein the upper substrate is disposed on the connections, and wherein the upper semiconductor chip is disposed on the upper substrate.

4. The semiconductor package of claim 1, wherein an uppermost surface of the connections is positioned at a level higher than the uppermost surface of the protection film.

5. The semiconductor package of claim 1, wherein the lower semiconductor chip comprises: a bottom surface facing the substrate, a top surface opposite the bottom surface, and a side surface between the bottom surface and the top surface, wherein the top surface is covered by the protection film, and the side surface is covered by the molding film.

6-10. (canceled)

11. A semiconductor package comprising:
a lower package having terminals;
an upper package on the lower package, the upper package having terminals;
conductive package connections electrically connecting the terminals of the lower package and the upper package;
the lower package comprising:
a lower semiconductor chip mounted to and electrically interfacing with a lower substrate, the conductive package connections horizontally surrounding the lower semiconductor chip;
a protection layer on a top surface of the lower semiconductor chip, the protection layer having an upper surface; and
a mold layer on the lower substrate and between the conductive package connections and sidewalls of the lower semiconductor chip;
wherein the conductive package connections are of a height that is greater than a combined height of the lower semiconductor chip and the protection layer such that a gap is present between the lower package and upper package.

12. The semiconductor package of claim 11, wherein the gap comprises an air gap.

13. The semiconductor package of claim 12, wherein the upper surface of the protection layer interfaces with the air gap.

14. The semiconductor package of claim 11, wherein the protection layer at least partially covers a top surface of the lower semiconductor chip.

15. The semiconductor package of claim 11, wherein the protection layer completely covers the top surface of the lower semiconductor chip.

16. The semiconductor package of claim 11, wherein the mold layer covers entire sidewalls of the lower semiconductor chip.

17. The semiconductor package of claim 11, wherein the mold layer covers entire sidewalls of the protection layer.

18. The semiconductor package of claim 11, further comprising lower electrical connectors connecting terminals at an underside of lower semiconductor chip with terminals of an upper surface of the lower substrate, and wherein the mold layer is further present between the lower electrical connectors.

19. The semiconductor package of claim 11 wherein the upper package comprises an upper substrate and an upper semiconductor chip on the upper substrate.

20. The semiconductor package of claim 11 wherein the upper surface of the protection layer is at substantially a same vertical position as an upper surface of the mold layer.
